(19) United States
(12) Patent Application Publication
(10) Pub. No.: US 2016/0005842 A1
(43) Pub. Date: Jan. 7, 2016

(54) POWER SEMICONDUCTOR DEVICE AND METHOD OF MANUFACTURING THE SAME

(71) Applicant: SAMSUNG ELECTRO-MECHANICS CO., LTD., Suwon-Si (KR)

(72) Inventors: Jae Hoon PARK, Suwon-Si (KR); Chang Su JANG, Suwon-Si (KR); Kyu Hyun MO, Suwon-si (KR); In Hyuk SONG, Suwon-Si (KR)

(73) Assignee: SAMSUNG ELECTRO-MECHANICS CO., LTD., Suwon-Si (KR)

(21) Appl. No.: 14/495,887

(22) Filed: Sep. 25, 2014

(30) Foreign Application Priority Data
Jul. 1, 2014 (KR) 10-2014-0081591

(51) Int. Cl. H01L 29/739; H01L 29/66

(52) U.S. Cl. CPC H01L 29/7395; H01L 29/66348

(57) ABSTRACT

A power semiconductor device may include a drift region including a base layer and a surface semiconductor layer disposed on the base layer and having a first conductivity type; a field insulating layer disposed on the base layer, embedded in the surface semiconductor layer, and including an opening portion; and a collector region disposed below the base layer and having a second conductivity type. The field insulating layer is formed in the drift region to limit movement of holes, whereby conduction loss of the power semiconductor device may be significantly decreased.

### CROSS-REFERENCE TO RELATED APPLICATION

This application claims the benefit of Korean Patent Application No. 10-2014-0081591 filed on Jul. 1, 2014, with the Korean Intellectual Property Office, the disclosure of which is incorporated herein by reference.

### BACKGROUND

The present disclosure relates to a power semiconductor device and a method of manufacturing the same.

Recently, in accordance with the accelerated development of various types of insulated gate bipolar transistor (IGBT) device, IGBT devices have been widely used in large capacity industrial products and electric vehicles, as well as in home appliances.

The largest advantage of IGBT devices is bipolar operations, unlike a metal oxide semiconductor field effect transistor (MOSFET), which may cause a conductivity modulation phenomenon, thereby decreasing series resistance that depends on a raw material of a wafer at the time of a turn-on operation.

Particularly, in the case that series resistance is decreased to significantly decrease forward conduction loss as compared with the MOSFET with respect to high withstand and high current products, whereby power loss may be decreased.

Therefore, in the field of IGBT technology, a technology capable of significantly increasing the conductivity modulation phenomenon has recently been developed. Particularly, a technology of accumulating holes has been actively developed.

In IGBT devices, holes are injected into a p-type collector layers and gradually disappear from the collector layer toward an emitter layer, such that conduction loss is increased from the collector layer toward the emitter layer.

In order to solve this problem, a technology of decreasing an interval between trench gates, a final movement path of the holes, that is, a width of a MESA region, to limit movement of the holes has been used.

The following Related Art Document (Patent Document 1) relates to a semiconductor device and a method of manufacturing the same.

### RELATED ART DOCUMENT

### (Patent Document 1) KR 10-2009-0028917

### SUMMARY

An exemplary embodiment in the present disclosure may provide a power semiconductor device and a method of manufacturing the same.

According to an exemplary embodiment in the present disclosure, a power semiconductor device may include: a drift region including a base layer and a surface semiconductor layer disposed on the base layer and having a first conductivity type; a field insulating layer disposed on the base layer, embedded in the surface semiconductor layer, and including an opening part; a body region disposed on an inner side of an upper portion of the surface semiconductor layer and having a second conductivity type; an emitter region disposed on an inner side of an upper portion of the body region, having an impurity concentration higher than that of the drift region, and having the first conductivity type; and a collector region disposed below the base layer and having the second conductivity type.

The base layer and the surface semiconductor layer may abut each other in the opening part.

The body region may be disposed so as to be spaced apart from the field insulating layer.

A thickness of the surface semiconductor layer may be adjusted according to a depth of the body region.

A width of the opening part may be 1 μm or less.

The power semiconductor device may further include trench gates disposed so as to penetrate from the body region into the surface semiconductor layer and including a gate insulating layer formed on a surface thereof and a conductive material filled therein.

A thickness of the surface semiconductor layer may be adjusted according to a depth of the body region and a depth of the trench gate.

According to an exemplary embodiment in the present disclosure, a method of manufacturing a power semiconductor device may include: preparing a base substrate having a first conductivity type; forming a mask pattern on the base substrate; forming a field insulating layer on the base substrate, exposed except for a portion covered by the mask pattern; forming an opening portion in the field insulating layer by removing the mask pattern; forming a surface semiconductor layer on the base substrate exposed by the opening portion to bury the field insulating layer in the surface semiconductor layer; forming a body region by implanting second conductivity type impurities into an upper portion of the surface semiconductor layer; forming an emitter region by implanting first conductivity type impurities into an upper portion of the body region; and forming a collector region by implanting second conductivity type impurities into a lower portion of the base substrate.

The surface semiconductor layer may be formed by an epitaxial method.

The forming of the body region may be performed so that the body region is spaced apart from the field insulating layer.

A thickness of the surface semiconductor layer may be adjusted according to a depth of the body region.

A width of the opening portion may be 1 μm or less.

The mask pattern may be formed of a nitride layer.

The opening portion may be formed by a wet cleaning process.

The method of manufacturing a power semiconductor device may further include, after the preparing of the base substrate, forming trench gates by etching the surface semiconductor layer, forming a gate insulating layer on a surface thereof, and disposing a conductive material therein.

A thickness of the surface semiconductor layer may be adjusted according to a depth of the body region and a depth of the trench gate.

### BRIEF DESCRIPTION OF DRAWINGS

The above and other aspects, features and other advantages will be more clearly understood from the following detailed description taken in conjunction with the accompanying drawings, in which:

FIG. 1 is a schematic cross-sectional view of a power semiconductor device according to an exemplary embodiment in the present disclosure;

FIG. 2 is a schematic cross-sectional view of a power semiconductor device according to another exemplary embodiment in the present disclosure; and

FIGS. 3A through 3E are schematic cross-sectional views illustrating processes of a method of manufacturing a power semiconductor device according to an exemplary embodiment in the present disclosure.

### DETAILED DESCRIPTION

Hereinafter, embodiments in the present disclosure will be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

A power switch may be implemented by any one of a power metal oxide semiconductor field effect transistor (MOSFET), an insulated gate bipolar transistor (IGBT), several types of thyristors, and devices similar to the above-mentioned devices. Most of new technologies disclosed herein will be described based on the IGBT. However, several exemplary embodiments disclosed herein are not limited to the IGBT, but may also be applied to other types of power switch technologies including a power MOSFET and several types of thyristors in addition to the IGBT. Further, several exemplary embodiments in the present disclosure will be described as including specific p-type and n-type regions. However, conductivity types of several regions disclosed herein may be similarly applied to devices having conductivity types opposite thereto.

In addition, an n-type or a p-type used herein may be defined as a first conductivity type or a second conductivity type. Meanwhile, the first and second conductivity types mean different conductivity types.

Further, generally, ‘+’ denotes a state in which a region is heavily doped and ‘−’ denotes a state in which a region is lightly doped. Hereinafter, in order to make a description clear, first and second conductivity types are denoted by an n-type and a p-type, respectively, but are not limited thereto.

### Power Semiconductor Device

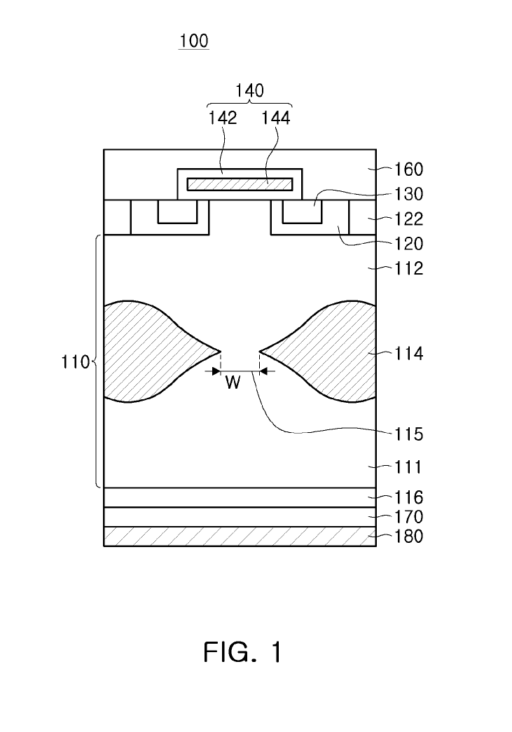

FIG. 1 is a schematic cross-sectional view of a power semiconductor device according to an exemplary embodiment in the present disclosure.

As shown in FIG. 1, a power semiconductor device 100 according to an exemplary embodiment in the present disclosure may include a drift region 110 including a base layer 111 and a surface semiconductor layer 112 disposed on the base layer 111 and having a first conductivity type, a field insulating layer 114 disposed on the base layer 111, embedded in the surface semiconductor layer 112, and including an opening portion 115, a body region 120 disposed on an inner side of an upper portion of the surface semiconductor layer 112 and having a second conductivity type, an emitter region 130 disposed on an inner side of an upper portion of the body region 120, having an impurity concentration higher than that of the drift region 110, and having the first conductivity type, and a collector region 170 disposed below the base layer 111 and having the second conductivity type.

The drift region 110 may have a low concentration of n-type conductivity type and include the base layer 111 and the surface semiconductor layer 112 disposed on the base layer 111.

The base layer 111 may have a comparatively thick thickness in order to maintain a withstand voltage of the device.

The base layer 111 may further include a buffer region 116 disposed therebeneath, wherein the buffer region 116 has a high concentration of n-type conductivity type.

The buffer region 116 may serve to block an extension of a depletion region of the power semiconductor device at the time of the extension of the depletion region, thereby assisting in maintaining the withstand voltage of the power semiconductor device. In the case in which the buffer region 116 is formed, a thickness of the base layer 111 may be decreased, such that the power semiconductor device may be miniaturized.

The collector region 170 having a high concentration of p-type conductivity type may be disposed below the base layer 111 or beneath the buffer region 116.

In the case in which the power semiconductor device is the IGBT, the collector region 170 may provide holes to the power semiconductor device 100.

A conductivity modulation phenomenon that conductivity in the drift region 110 is increased tens to hundreds of times due to high concentration injection of the holes, which are minor carriers, may occur.

The field insulating layer 114 including the opening portion 115 may be embedded and disposed in the drift region 110.

The field insulating layer 114 may be an oxide layer having a bird's beak shape.

The opening portion 115 may be disposed bird's beaks of the field insulating layer 114 and may be a path for moving electron-hole carriers in the drift region 110.

The bird's beaks may be disposed at both sides of the base layer 111 that are exposed, respectively.

Since the field insulating layer 114 has the bird's beak shape, it may limit movement of the holes provided from the collector region 170.

That is, the holes may be intensively accumulated in the vicinity of the bird's beaks of the field insulating layer 114.

When the holes are accumulated below the field insulating layer 114, the conductive modulation phenomenon may be significantly increased to significantly decrease conduction loss.

Generally, a degree of a magnitude of the conductivity modulation phenomenon may be determined by a magnitude of a ratio between an electron carrier concentration and a hole carrier concentration.

In order to significantly increase a ratio between two carrier concentrations having polarities opposite to each other, the opening portion needs to be disposed in the drift region. Here, a carrier concentration of the drift region doped with phosphorous may be 1.9e¹⁴ cm⁻³ or less.

The opening portion may be formed more adjacently to the body region than to the collector region. As the opening portion becomes close to the body region, a turn-on resistance and switching loss at the time of switching to a turn-off may be decreased.

The base layer 111 and the surface semiconductor layer 112 in the drift region 110 may abut each other in the opening portion 115.

The opening portion 115 may be the path for moving the electron-hole carriers in the drift region 110.

A width of the opening portion 115 may be 1 μm or less.

When the width of the opening portion 115 is 1 μm or less, the conductive modulation phenomenon may be significantly increased to significantly decrease the conduction loss.

In the related art, the opening portion was formed at a width exceeding 1 μm due to a limitation of a process. However, in an exemplary embodiment in the present disclosure, the width of the opening portion may be easily adjusted to be 1 μm or less.

The body region 120 having the p-type conductivity type may be disposed at the inner side of the upper portion of the surface semiconductor layer 112 of the drift region 110.

The body region 120 may be disposed so as to be spaced apart from the field insulating layer 114.

The body region 120 is disposed so as to be spaced apart from the field insulating layer 114, whereby generation of gate noise due to the accumulated holes may be prevented.

Therefore, a thickness of the surface semiconductor layer 112 may be adjusted according to a depth of the body region 120.

The emitter region 130 having an n-type impurity concentration higher than that of the drift region 110 may be disposed at the inner side of the upper portion of the body region 120.

A gate 140 may be disposed on the body region 120.

The gate 140 may be formed by forming a gate insulating layer 142 on the body region 120 and stacking a conductive material 144 on the gate insulating layer 142.

The gate insulating layer 142 may be formed of a silicon oxide (SiO₂), but is not limited thereto.

The conductive material 144 may be formed of a poly-silicon (poly-Si) or a metal, but is not limited thereto.

The conductive material 144 may be electrically connected to a gate electrode (not shown) and may control an operation of the power semiconductor device 100 according to an exemplary embodiment in the present disclosure.

In the case in which a positive voltage is applied to the conductive material 144, a channel may be formed at the upper portion of the body region 120.

In detail, when the positive voltage is applied to the conductive material 144, electrons present in the body region 120 may be pulled toward the gate 140 and be collected at the upper portion of the body region 120, such that the channel may be formed.

That is, the gate may pull the electrons in a depletion region in which the carriers are not present by recombination between the electrons and the holes due to a p-n junction, such that the channel may be formed, whereby a current may flow.

Here, the movement of the holes provided from the collector region 170 may be limited by the field insulating layer 114.

When the holes are accumulated in the vicinity of the bird's beaks of the field insulating layer 114, a time in which the holes may stay in the drift region 110 may be increased to significantly increase the conductivity modulation phenomenon.

Therefore, since a time in which the electrons that may be pulled by the gate 140 are supplied is increased, the conduction loss may be significantly decreased through the significant increase in the conductive modulation phenomenon.

An emitter metal layer 160 may be disposed on upper surfaces of the emitter region 130 and the body region 120 that are exposed, and a collector metal layer 180 may be disposed on a lower surface of the collector region 170.

Referring to FIG. 1, the power semiconductor device 100 according to an exemplary embodiment in the present disclosure may include a hole movement region 122 having a high concentration of p-type conductivity type.

The hole movement region 122 may at least partially abut the drift region 110 while penetrating through the body region 120.

Since the hole movement region 122 has the high concentration of p-type conductivity type, a resistance to a hole current in the hole movement region 122 may be very low.

Since the hole movement region 122 partially abuts onto the drift region 110, the holes accumulated in the drift region 110 may flow into the hole movement region 122 and then exit to the emitter metal layer 160.

That is, movement of the holes to the emitter region 130 may be prevented to prevent a parasitic thyristor from being operated. When the hole movement region 122 is formed, reliability of the power semiconductor device may be improved.

As described above, in the power semiconductor device according to an exemplary embodiment in the present disclosure, the holes may be accumulated in the drift region by the field insulating layer. Therefore, the conductive modulation phenomenon may be significantly increased to significantly decrease the conduction loss.

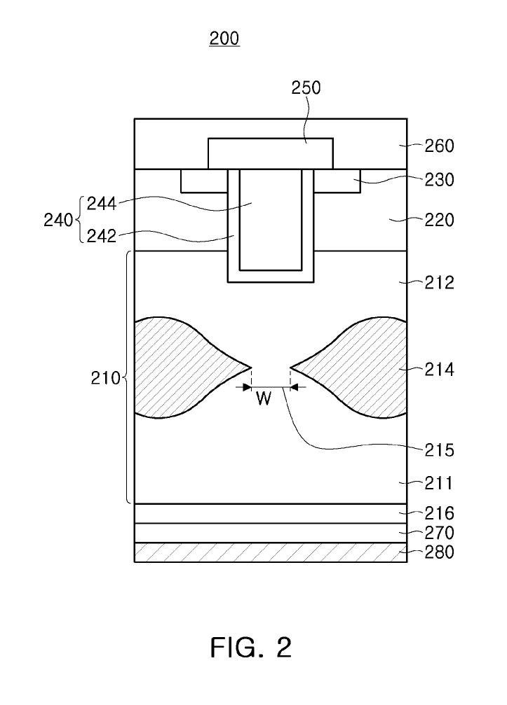

FIG. 2 is a schematic cross-sectional view of a power semiconductor device according to another exemplary embodiment in the present disclosure.

A description for components that are the same as the components shown in FIG. 1 among components shown in FIG. 2 will be omitted.

Referring to FIG. 2, a power semiconductor device 200 may further include trench gates 240 disposed so as to penetrate from the body region 220 into the surface semiconductor layer 212 and including a gate insulating layer 242 formed on a surface thereof and a conductive material 244 filled therein.

A silicon oxide layer may be disposed on the body region 220.

The field insulating layer 214 including the opening portion 215 may be embedded and disposed in the drift region 210.

The field insulating layer 214 may be an oxide layer having a bird's beak shape, and the opening portion 215 may be disposed between bird's beaks of the field insulating layer 214.

The bird's beaks may be disposed at both sides of the base layer 211 that are exposed, respectively.

Since the field insulating layer 214 has the bird's beak shape, the holes may be intensively accumulated in the vicinity of the bird's beaks of the field insulating layer 214.

When the holes are accumulated below the field insulating layer 214, the conductive modulation phenomenon may be significantly increased to significantly decrease the conduction loss.

As the opening portion becomes more adjacent to the trench gate than to the collector region, a turn-on resistance and switching loss at the time of switching to a turn-off may be decreased.

The trench gates 240 may be lengthily formed in one direction and be arranged at predetermined intervals in a direction perpendicular to a direction in which they are lengthily formed.

The trench gate 240 may include the gate insulating layer 242 disposed at portions abutting onto the surface semiconductor layer 212, the body region 220, and the emitter region 230.

The gate insulating layer 242 may be formed of a silicon oxide (SiO₂), but is not limited thereto.

The conductive material 244 may be filled in the trench gate 240.

The conductive material 244 may be formed of a poly-silicon (poly-Si) or a metal, but is not limited thereto.

The conductive material 244 may be electrically connected to a gate electrode (not shown) and may control an operation of the power semiconductor device 200 according to another exemplary embodiment in the present disclosure.

In the case in which a positive voltage is applied to the conductive material 244, a channel may be formed in the body region 220.

In detail, when the positive voltage is applied to the conductive material 244, electrons present in the body region 220 may be pulled toward the trench gate 240 and be collected at the trench gate 240, such that the channel may be formed.

That is, the trench gate 240 may pull the electrons in a depletion region in which the carriers are not present by recombination between the electrons and the holes due to a p-n junction, such that the channel may be formed, whereby a current may flow.

Here, when the holes provided from the collector region 270 are accumulated in the vicinity of the bird's beaks of the field insulating layer 214, a time in which the holes may stay in the drift region 210 may be increased to significantly increase the conductivity modulation phenomenon.

Therefore, since a time in which the electrons that may be pulled by the trench gate 240 are supplied is increased, the conduction loss may be significantly decreased through the significant increase in the conductive modulation phenomenon.

The field insulating layer 214 may be disposed so as to be spaced apart from the trench gate. The field insulating layer 214 is disposed so as to be spaced apart from the trench gate 240, whereby generation of gate noise due to the accumulated holes may be prevented.

Therefore, a thickness of the surface semiconductor layer 212 may be adjusted according to a depth of the body region 210 and a depth of the trench gate 240.

As described above, in the power semiconductor device according to another exemplary embodiment in the present disclosure, the conductivity modulation phenomenon may be significantly increased and the conductor loss may be significantly decreased, such that reliability may be increased in an entire operation of the power semiconductor device.

### Method of Manufacturing Power Semiconductor Device

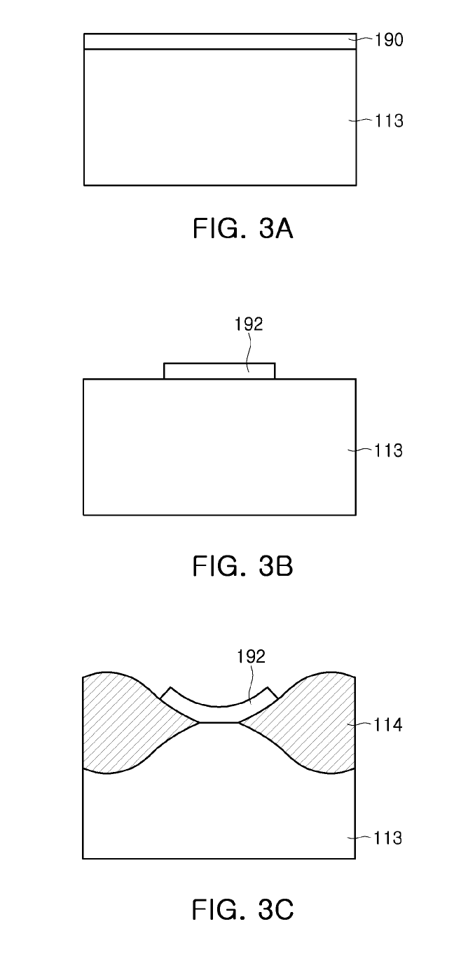

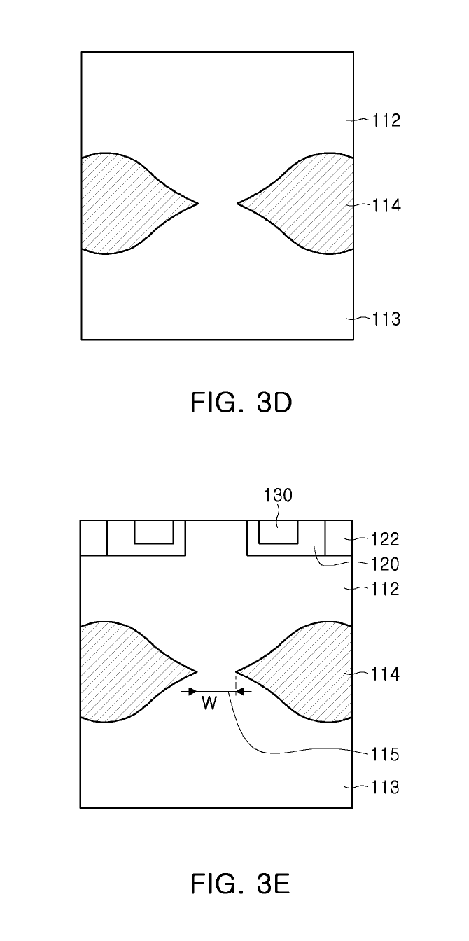

FIGS. 3A through 3E are schematic cross-sectional views illustrating processes of a method of manufacturing a power semiconductor device according to an exemplary embodiment in the present disclosure.

Referring to FIGS. 3A through 3E, a method of manufacturing a power semiconductor device according to an exemplary embodiment in the present disclosure may include: preparing a base substrate 113 having the first conductivity type, forming a mask pattern 192 on the base substrate 113, forming the field insulating layer 114 on the base substrate 113 exposed except for a portion covered by the mask pattern 192, forming the opening portion 115 in the field insulating layer 114 by removing the mask pattern 192, forming the surface semiconductor layer 112 on the base substrate 113 exposed by the opening portion 115 to bury the field insulating layer 114 in the surface semiconductor layer 112, forming the body region 120 by implanting second conductivity type impurities into an upper portion of the surface semiconductor layer 112, forming the emitter region 130 by implanting first conductivity type impurities into an upper portion of the body region 120, and forming the collector region 170 by implanting second conductivity type impurities into a lower portion of the base substrate 113.

First, referring to FIG. 3A, the base substrate 113 having the first conductivity type may be prepared. Here, the base substrate 113 may have a low concentration of n-type conductivity type, but is not limited thereto.

Next, an insulating layer 190 may be formed on the base substrate 113.

The insulating layer 190 may be formed of a nitride layer, which may be formed of a silicon nitride (SiN).

The insulating layer 190 may further include an oxide layer. The oxide layer may be formed of a silicon oxide (SiO₂) and may be formed between the base substrate 113 and the nitride layer.

Here, the insulating layer 190 may be formed by a deposition method.

Next, referring to FIG. 3B, a photosensitive layer may be applied onto the insulating layer 190 and be exposed and developed to form a photosensitive layer pattern (not shown) exposing a bonded region.

The insulating layer 190 may be etched using the photosensitive layer pattern as a mask to form the mask pattern 192 exposing the base substrate 113 on which the bonded region is formed. Then, the photosensitive layer pattern may be removed.

Next, referring to FIG. 3C, the field insulating layer 114 may be formed on the base substrate 113 exposed except for the portion covered by the mask pattern 192.

The field insulating layer 114 may be the oxide layer having the bird's beak shape.

The bird's beaks of the field insulating layer 114 may be formed at both sides of the base substrate 113 that are exposed, respectively. Here, the field insulating layer 114 may be formed by a local oxidation of silicon (LOCOS) method.

The mask pattern 192 may be present on the field insulating layer 114 in a form in which it is bent after the field insulating layer 114 is formed.

Next, referring to FIG. 3D, the opening portion may be formed in the field insulating layer 114 by removing the mask pattern 192.

The mask pattern 192 may be removed by wet etching or dry etching.

Then, the opening portion exposing the base substrate 113 may be formed between the two adjacent field insulating layers 114 by performing a wet cleaning process of using an oxide etchant without an additional mask process.

When the opening portion is formed by the wet cleaning process without the additional mask process, a process may be simplified to secure a process margin.

The opening portion may be the path for moving the electron-hole carriers in the drift region 112 and 113.

A width of the opening portion may be 1 μm or less. When the width of the opening portion is 1 μm or less, the conductive modulation phenomenon may be significantly increased to significantly decrease the conduction loss.

In the related art, the opening portion was formed at a width exceeding 1 μm due to a limitation of a process. However, in an exemplary embodiment in the present disclosure, the wet cleaning process is performed without the additional mask process, whereby the width of the opening portion may be easily adjusted to be 1 μm or less.

After the wet cleaning process is performed, an additional process such as a wet treatment process of using an oxide etchant or a high temperature heat treatment process performed without an oxide atmosphere may be performed.

When the additional process is performed, a surface of the base substrate exposed in the opening portion 115 between the field insulating layers 114 may be exposed in a state in which impurities are hardly present thereon.

In the case in which the high temperature heat treatment process is performed as the additional process, silicon lattices may be rearranged around the base substrate that is irregular due to formation of the file insulating layer 114. Therefore, a silicon lattice structure around the base substrate may be stable.

Next, the surface semiconductor layer 112 may be formed on the base substrate 113 exposed by the opening portion 115 to bury the field insulating layer 114 in the surface semiconductor layer 112.

Here, the surface semiconductor layer 112 may be formed by an epitaxial method using the base substrate exposed by the opening portion 115 as a seed layer.

The surface semiconductor layer 112 may be formed at a height higher than that of the field insulating layer 114.

The field insulating layer 114 including the opening portion 115 may be embedded in the surface semiconductor layer 112.

Then, a chemical mechanical polishing (CMP) process may be performed to planarize a surface of the surface semiconductor layer 112, but is not limited thereto.

Next, referring to FIG. 3E, the body region 120 may be formed by implanting the second conductivity type impurities into the upper portion of the surface semiconductor layer 112.

The body region 120 may be formed by implanting p-type impurities into the upper portion of the surface semiconductor layer 112.

The body region 120 may have a p-type conductivity type to form a p-n junction with the drift region 112 and 113.

The body region 120 may be disposed so as to be spaced apart from the field insulating layer 114. The body region 120 is disposed so as to be spaced apart from the field insulating layer 114, whereby generation of gate noise due to the accumulated holes may be prevented.

Therefore, a thickness of the surface semiconductor layer 112 may be adjusted according to a depth of the body region 120.

Next, the emitter region 130 having an impurity concentration higher than that of the drift region 112 and 113 may be formed at the inner side of the upper portion of the body region 120.

Here, the emitting region 130 may be formed by implanting the high concentration of n-type impurities into the upper portion of the body region 120.

Next, the hole movement region 122 may be formed so as to at least partially abut the drift region 112 and 113 while penetrating through the body region 120.

Since the hole movement region 122 is formed using a high concentration of p-type impurities, a resistance to a hole current in the hole movement region 122 may be very low.

Next, referring to FIG. 1, the buffer region 116 may be formed by implanting n-type impurities into a rear surface of the base substrate.

The collector region 170 may be formed by implanting p-type impurities into a lower portion of the drift region 112 and 113 or a lower portion of the buffer region 116.

In the case in which the power semiconductor device is the IGBT, the collector region 170 may provide the holes to the power semiconductor device.

The conductivity modulation phenomenon that the conductivity in the drift region 112 and 113 is increased tens to hundreds of times due to the high concentration injection of the holes, which are the minor carriers, may occur.

The holes provided from the collector region 170 to the drift region 112 and 113 may be accumulated below the field insulating layer 114.

When the holes are intensively accumulated in the vicinity of the bird's beaks of the field insulating layer 114, the conductive modulation phenomenon may be significantly increased to significantly decrease the conduction loss.

Next, the gate 140 may be disposed on the body region 120.

The gate 140 may be formed by forming the gate insulating layer 142 on the body region 120 and stacking the conductive material 144 on the gate insulating layer 142.

The gate insulating layer 142 may be formed of the silicon oxide (SiO₂), but is not limited thereto.

The conductive material 144 may be formed of the poly-silicon (poly-Si) or the metal, but is not limited thereto.

The emitter metal layer 160 may be formed on the upper surfaces of the emitter region 130 and the body region 120 that are exposed, and the collector metal layer 180 may be formed on the lower surface of the collector region 170.

Referring to FIG. 2, after the base substrate is prepared, the trench gates 240 may be formed.

The trench gate 240 may be formed by etching an upper portion of the surface semiconductor layer 212, forming the gate insulating layer 242 on a surface thereof, and disposing the conductive material 244 therein.

A thickness of the surface semiconductor layer 212 may be adjusted according to a depth of the body region 220 and a depth of the trench gate 240.

The trench gates 240 may be lengthily formed in one direction and be arranged at predetermined intervals in a direction perpendicular to a direction in which they are lengthily formed.

The gate insulating layer 242 may be formed at portions abutting onto the surface semiconductor layer 212, the body region 220, and the emitter region 230.

The gate insulating layer 242 may be formed of the silicon oxide (SiO₂), but is not limited thereto.

The conductive material 244 may be formed of the poly-silicon (poly-Si) or the metal, but is not limited thereto.

As described above, in the method of manufacturing a power semiconductor device according to an exemplary embodiment in the present disclosure, the opening portion of the field insulating layer may be formed by the wet cleaning process without the additional mask process, such that the process may be simplified to secure the process margin.

As set forth above, according to exemplary embodiments in the present disclosure, the power semiconductor device capable of significantly increasing the conductivity modulation phenomenon, and the method of manufacturing the same may be provided.

While exemplary embodiments have been shown and described above, it will be apparent to those skilled in the art that modifications and variations could be made without departing from the scope of the invention as defined by the appended claims.

What is claimed is:

1. A power semiconductor device comprising:
a drift region of a first conductivity type including a base layer and a surface semiconductor layer disposed on the base layer;
a field insulating layer disposed on the base layer, embedded in the surface semiconductor layer, and including an opening portion;
a body region of a second conductivity type disposed on an inner side of an upper portion of the surface semiconductor layer;
an emitter region of the first conductivity type disposed on an inner side of an upper portion of the body region, and having an impurity concentration higher than that of the drift region; and
a collector region of the second conductivity type disposed below the base layer.

2. The power semiconductor device of claim 1, wherein the base layer and the surface semiconductor layer abut each other in the opening portion.

3. The power semiconductor device of claim 1, wherein the body region is disposed so as to be spaced apart from the field insulating layer.

4. The power semiconductor device of claim 1, wherein a thickness of the surface semiconductor layer is adjusted according to a depth of the body region.

5. The power semiconductor device of claim 1, wherein a width of the opening portion is 1 μm or less.

6. The power semiconductor device of claim 1, further comprising trench gates disposed so as to penetrate from the body region into the surface semiconductor layer and including a gate insulating layer formed on a surface thereof and a conductive material filled therein.

7. The power semiconductor device of claim 6, wherein a thickness of the surface semiconductor layer is adjusted according to a depth of the body region and a depth of the trench gate.

8. A method of manufacturing a power semiconductor device, comprising:
preparing a base substrate of a first conductivity type;
forming a mask pattern on the base substrate;
forming a field insulating layer on the base substrate exposed, except for a portion covered by the mask pattern;
forming an opening portion in the field insulating layer by removing the mask pattern;
forming a surface semiconductor layer on the base substrate exposed by the opening portion to bury the field insulating layer in the surface semiconductor layer;
forming a body region by implanting second conductivity type impurities into an upper portion of the surface semiconductor layer;
forming an emitter region by implanting first conductivity type impurities into an upper portion of the body region; and
forming a collector region by implanting second conductivity type impurities into a lower portion of the base substrate.

9. The method of manufacturing a power semiconductor device of claim 8, wherein the surface semiconductor layer is formed by an epitaxial method.

10. The method of manufacturing a power semiconductor device of claim 8, wherein the forming of the body region is performed so that the body region is spaced apart from the field insulating layer.

11. The method of manufacturing a power semiconductor device of claim 8, wherein a thickness of the surface semiconductor layer is adjusted according to a depth of the body region.

12. The method of manufacturing a power semiconductor device of claim 8, wherein a width of the opening portion is 1 μm or less.

13. The method of manufacturing a power semiconductor device of claim 8, wherein the mask pattern is formed of a nitride layer.

14. The method of manufacturing a power semiconductor device of claim 8, wherein the opening portion is formed by a wet cleaning process.

15. The method of manufacturing a power semiconductor device of claim 8, further comprising, after the preparing of the base substrate, forming trench gates by etching the surface semiconductor layer, forming a gate insulating layer on a surface thereof, and disposing a conductive material therein.

16. The method of manufacturing a power semiconductor device of claim 15, wherein a thickness of the surface semiconductor layer is adjusted according to a depth of the body region and a depth of the trench gate.
